(19) United States
(12) Patent Application Publication
(10) Pub. No.: US 2010/0315080 A1
(43) Pub. Date: Dec. 16, 2010

(54) METAL DETECTOR

(76) Inventors: Andrew Duncan, Mundaring (AU); Gary Hooper, Westbourne Park (AU); Michael Asten, Hawthorn (AU)

Correspondence Address: DAVIS WRIGHT TREMAINE, LLP/Seattle, 1201 Third Avenue, Suite 2200, SEATTLE, WA, 98101-3045, US

(21) Appl. No.: 12/446,437

(22) PCT Filed: Oct. 23, 2007
(86) PCT No.: PCT/AU07/01610

§ 371 Date: Jul. 29, 2009

Related U.S. Application Data
(60) Provisional application No. 60/862,754, filed on Oct. 24, 2006.

(51) Int. Cl. G01R 33/02

(52) U.S. Cl. 324/258

(57) ABSTRACT

A metal detector is disclosed which comprises a transmitter arranged to generate a primary magnetic field, and at least one sensor arranged so as to sense a secondary magnetic field vector present after the transmitter has been turned off by measuring 3 substantially mutually orthogonal components of the secondary magnetic field. Each sensor is of a type arranged to sense a time-varying magnetic field.

### FIELD OF THE INVENTION

The present invention relates to a metal detector and, in particular, to a metal detector for detecting unexploded items of ordnance.

### BACKGROUND OF THE INVENTION

It is known that relatively large areas of military and former military sites contain unexploded items of ordnance (hereinafter referred to as “UXOs”) and in order to render such areas safe it is necessary to detect the UXOs and remove them.

Detection systems currently used are based on electromagnetic induction wherein a time-varying induced magnetic field interacts with buried metal objects, and analysis of a response or secondary magnetic field provides an indication as to the presence of an object. Generally, such systems include a sensor coil arranged to sense the rate of change of the response field, in particular a residual decay field generated as a result of electrical eddy currents induced in the buried metal object after the initial primary field has been turned off.

However, such metal detecting systems have a relatively high false alarm rate which renders retrieval of UXOs very expensive and time consuming.

### SUMMARY OF THE INVENTION

In accordance with a first aspect of the present invention, there is provided a metal detector comprising:
a transmitter arranged to generate a primary magnetic field; and
at least one sensor arranged so as to sense a secondary vector magnetic field present after the transmitter has been turned off by measuring 3 substantially mutually orthogonal components of the secondary magnetic field;
wherein each sensor is of a type arranged to sense the time-varying magnetic field vector.

In one embodiment, a plurality of sensors are provided.

In one arrangement, the transmitter is in the form of a coil and the metal detector includes three sensors, a first sensor being disposed substantially centrally of the transmitter coil, a second sensor being disposed adjacent and inwardly of a first side of the transmitter coil, and a third sensor being disposed adjacent and inwardly of a second opposite side of the transmitter coil.

In an alternative arrangement, the transmitter is in the form of a coil and the metal detector includes three sensors, a first sensor being disposed substantially centrally of the transmitter coil, a second sensor being disposed adjacent and outwardly of a first side of the transmitter coil, and a third sensor being disposed adjacent and outwardly of a second opposite side of the transmitter coil. In one embodiment, the distances of the second and third sensors from the first and second sides of the transmitter coil are selected such that the primary field at each of the second and third sensors is substantially equal and opposite to the primary field at the first sensor.

In an alternative arrangement, the transmitter is in the form of a coil and the metal detector includes three vector sensors, a first sensor being disposed substantially centrally of the transmitter coil, a second sensor being disposed outwardly of a first side of the transmitter coil, and a third sensor being disposed outwardly of a second opposite side of the transmitter coil, the distance between adjacent sensors being approximately equal to the length of a side of the transmitter coil.

In one embodiment, the metal detector further comprises means for reducing the magnitude of the primary field generated by the transmitter coil at an active area of each sensor. The means for reducing the primary field magnitude may comprise at least one nulling coil disposed substantially concentrically with the sensor. In one arrangement, two nulling coils are provided, a first nulling coil being disposed at a location upwardly of the or each sensor, and a second nulling coil disposed downwardly of the or each sensor.

In one arrangement, the nulling coils are connected in series with the transmitter and are of such size and spacing and number of wire turns that nulling is substantially achieved at the sensor when passing the transmitter current through the series connection of transmitter and nulling coils.

In one arrangement, the metal detector further comprises a control unit arranged to process response data produced by the or each sensor so as to reduce anomalies in the response data.

The control unit may be arranged to process the response data so as to produce leveled data by selecting a reference channel from a plurality of data channels produced by the or each sensor and subtracting the amplitude of the reference channel from each of the other channels.

The control unit may be arranged to process the response data so as to produce stripped data by subtracting a background response amplitude from each of the channels produced by the or each sensor.

In accordance with a second aspect of the present invention, there is provided a method of detecting metal, said method comprising:
generating a primary magnetic field;
turning the primary magnetic field off; and
sensing 3 mutually orthogonal components of a secondary magnetic field vector present after the primary magnetic field has been turned off.

In one arrangement, the method further comprises:
for each sensor and for each component of the secondary magnetic field, selecting a reference channel from a plurality of data channels produced by the sensor and subtracting the amplitude of the reference channel from each of the other channels so as to produce leveled data.

In one arrangement, the method further comprises:
for each sensor and for each component of the secondary magnetic field, subtracting a background response amplitude from each of the response amplitudes produced by the component so as to produce stripped data.

In accordance with a third aspect of the present invention, there is provided a device for detecting a UXO, the device including a metal detector comprising:
a transmitter arranged to generate a primary magnetic field;
means for turning the transmitter off; and
at least one sensor arranged so as to sense 3 mutually orthogonal components of a secondary magnetic field present after the transmitter has been turned off;
wherein each sensor is of a type arranged to sense magnetic field magnitude.

### BRIEF DESCRIPTION OF THE DRAWINGS

The present will now be described, by way of example only, with reference to the accompanying drawings, in which:

FIG. 1 is a schematic diagram of a metal detector in accordance with an embodiment of the present invention;

FIG. 2 is a schematic diagram of a metal detector in accordance with an alternative embodiment of the present invention;

FIG. 3 is a schematic diagram of a metal detector in accordance with a further alternative embodiment of the present invention;

FIG. 4 is a diagrammatic representation of a sensor of the metal detector shown in FIGS. 1 to 3;

FIG. 5 is a diagram illustrating locations of scrap metal and a UXO in a model;

FIG. 6a is a modelled plot of a response from one component of a vector sensor of the type measuring magnetic field magnitude of the secondary field response for the model shown in FIG. 5;

FIG. 6b is a modelled plot of a response from one component of a sensor of the type measuring the time rate of change of magnetic field of the secondary field response for the model shown in FIG. 5;

FIG. 7 is a schematic diagram illustrating a sensor of the metal detector shown in FIGS. 1 to 3 with incorporated nulling coils;

FIG. 8 is a diagrammatic representation illustrating exemplary level shift anomalies in responses produced by one component of a sensor of the metal detector shown in FIGS. 1 to 3;

FIG. 9 is a diagrammatic representation illustrating the response shown in FIG. 8 after application of a leveling algorithm;

FIG. 10 is a diagrammatic representation illustrating the response shown in FIG. 8 after application of a leveling algorithm and a stripping algorithm;

FIG. 11 is a plot illustrating a Z component response produced by a sensor of the metal detector shown in FIGS. 1 to 3;

FIG. 12 is a plot of the response shown in FIG. 12 after application of a leveling algorithm;

FIG. 13 is a plot illustrating the leveled response shown in FIG. 12 after application of a stripping algorithm; and

FIG. 14 shows responses produced by X, Y and Z components of a sensor after application of leveling and stripping algorithms for all three components of the secondary field response.

### DESCRIPTION OF AN EMBODIMENT OF THE INVENTION

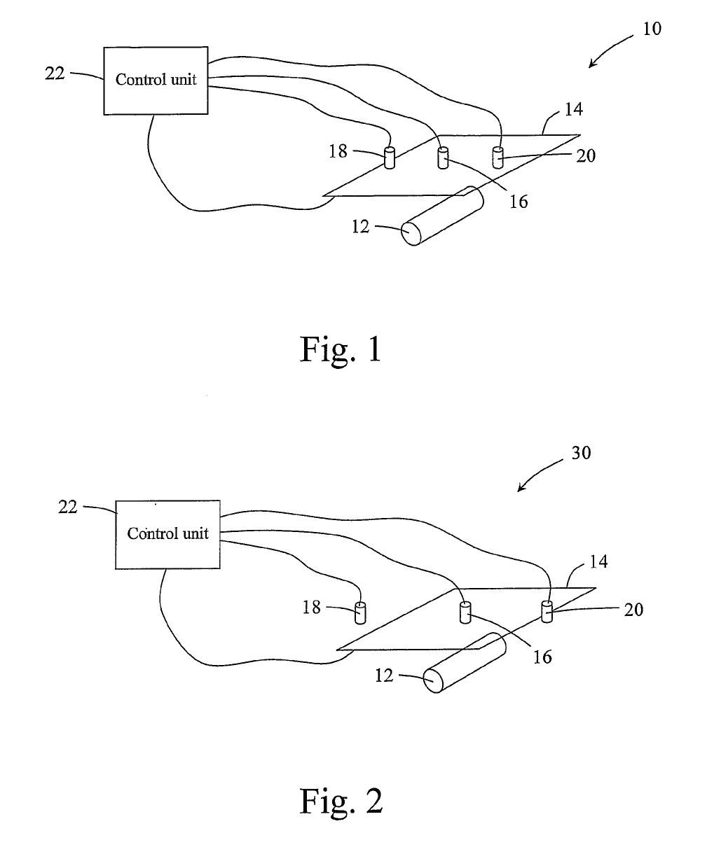

Referring to FIG. 1 of the drawings, there is shown a metal detector 10, in this example for use in detecting a UXO 12 and distinguishing the UXO 12 from scrap metal and other non-UXO objects.

The metal detector 10 includes a transmitter coil 14 which in this example is of 1 m×1 m square configuration. Disposed inside the transmitter coil 14 are first, second and third vector sensors 16, 18 and 20 respectively. The sensors 16, 18, 20 are of magnetometer type and, as such, are arranged to generate an output signal representative of the magnitude of the time-varying vector magnetic field present at the sensors 16, 18, 20.

It will be understood that by providing a plurality of spaced sensors, the ability of the metal detector to determine orientation of a target object is increased.

As shown in more detail diagrammatically in FIG. 4, each of the vector sensors 16 includes three sensor components, a first magnetometer 40, a second magnetometer 42 extending in a generally orthogonal direction to the first magnetometer 40, and a third magnetometer 44 extending in a direction generally orthogonal to both the first and second magnetometers 40, 42. Since the first, second and third magnetometers 40, 42, 44 are disposed in mutually orthogonal orientations, the first, second and third magnetometers sense mutually orthogonal components of a magnetic field which will be referred to hereinafter as X, Y and Z components of the magnetic field.

The metal detector 10 also includes a control unit 22 arranged to control and coordinate operation of the transmitter 14, to control and coordinate reception of signals from the sensors 16, 18, 20, and to process the received signals so as to produce useable data indicative of detected metallic objects.

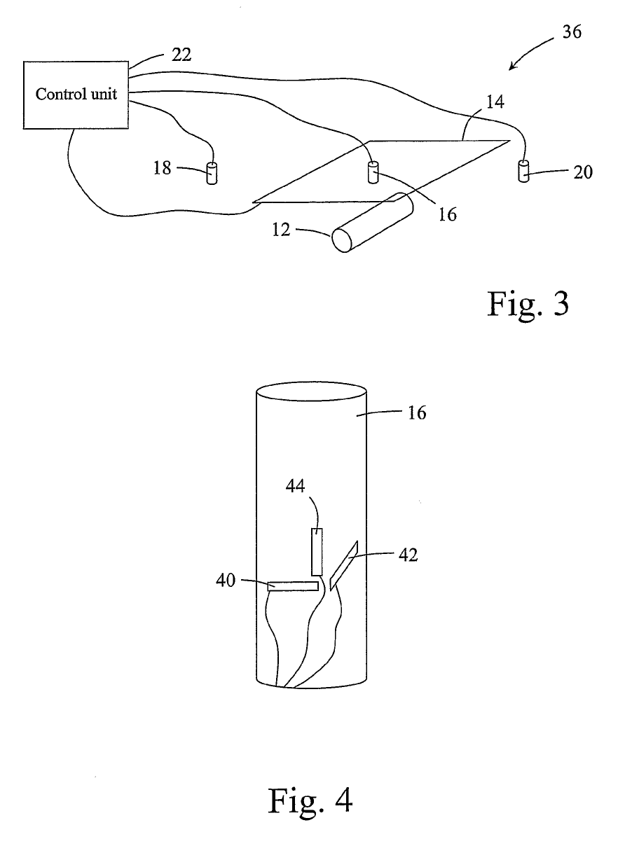

Alternative metal detectors 30, 36 are shown in FIGS. 2 and 3, the alternative metal detectors 30, 36 being of similar configuration to the metal detector 10 shown in FIG. 1 except that with the metal detector 30 shown in FIG. 2 the second and third vector sensors 18, 20 are disposed adjacent and outwardly of the transmitter 14, and with the metal detector 36 shown in FIG. 3 the second and third vector sensors 18, 20 are disposed outwardly of the transmitter 14 but not adjacent the transmitter 14.

With the metal detector 10 shown in FIG. 1, the primary field adjacent and inwardly of the transmitter 14 at the second and third sensors 18, 20 will be significantly larger than the primary field at the center of the transmitter 14. This places a heavy additional demand on receiver processing required to be carried out by the central unit 22.

The geometry of the metal detector 30 shown in FIG. 2 has sensors placed adjacent and outwardly of the transmitter 14, and the metal detector 30 is configured such that the primary field at the second and third sensors 18, 20 is substantially equal and opposite to the primary field at the transmitter center. The metal detector 30 also has the advantage that in this example for a target at 0.5 m depth below ground, the signal at the second and third sensors as a ratio of signal at the first sensor (signal strength ratio) is of the order of 0.3, and hence the second and third sensors 18, 20 and the first sensor 16 will have comparable signal/noise characteristics when used for precise location and discrimination studies on targets in the critical 0.5 m burial zone.

The geometry of the metal detector 36 shown in FIG. 3 has a wide spread of vector sensors, and is advantageous in terms of subtending a large angle relative to a target, thereby facilitating improved target position location. However, a disadvantage is that the ratio of signal strength from a target detected by the first sensor 16 and the second and third sensors 18, 20 is poor.

It will be understood that by using a sensor arranged to detect magnetic field magnitude (hereinafter referred to as a “B field sensor”) instead of a magnetic field rate of change sensor (hereinafter referred to as a “dB/dt sensor”), improved detection of relatively deep, electrically conductive targets can be achieved and improved capability of distinguishing between UXOs and surface scrap can be obtained.

The decay time constant for a metal object such as a UXO is generally several times greater than the decay time constant for scrap material.

It will be appreciated that the magnetic field magnitude of a response generated by a metal target shortly after the primary field is turned off is proportional to the size and depth of the target.

It will also be appreciated that the time rate of change of the magnetic field magnitude of a response generated by a metal target shortly after the primary field is turned off is proportional to the size and depth of the target, and inversely proportional to the relevant decay time constant.

A comparison of differences between a dB/dt sensor such as a coil sensor and a B field sensor such as a magnetometer can be made with a simplified set of assumptions as follows:

For a target in the form of an intact UXO, assume a step response to a change in primary magnetic field given by the decay curve:

B(t)=Xexp(−t/τₜ)

where X is a constant set by transmitter-target-receiver magnetic coupling, and τₜ is the time constant of exponential decay of eddy currents induced in the target.

Suppose we also have an item of scrap, which typically has a shorter time constant τₛ, and a step response of the form:

B(t)=Yexp(−t/τₛ)

where Y is a constant set by transmitter-target-receiver magnetic coupling, and τₛ is the time-constant of exponential decay of eddy currents induced in the scrap.

A dB/dt coil sensor will see a combined response from these two objects given by:

dB(t)/dt=(X/τₜ)exp(−t/τₜ)+(Y/τₛ)exp(−t/τₛ).

Suppose that in a field survey the target UXO and piece of scrap are giving a similar dB/dt response at early times (t<<τₛ), (t<<τₜ). This condition may be written in the form:

X/τ_{τ}=Y/τₛ

and by assumption above, the response ratio at early times is:

UXO:scrap=1.

Consider the same survey repeated using B-field sensors.

The combined response for the two objects is:

B(t)=Xexp(−t/τₜ)+Yexp(−t/τₛ)

and the response ratio at early times is:

UXO:scrap=X/Y=τtτₛ.

Accordingly, for a UXO (e.g. 150 mm shell) with a typical time constant of 30 msec and a scrap item with a typical time constant of 5 msec, this implies that a B-field measurement will provide a UXO:scrap discrimination advantage of 6:1 compared to a dB/dt measurement.

It will therefore be understood that using a B-field sensor enhances a UXO signal relative to a typical scrap signal, and improves sensitivity of the metal detector to deeper UXO targets.

It will also be understood that by using a mutually orthogonal 3 component sensor, significant information indicative of the characteristics of a buried object can be obtained. For example, with a 3 component B field sensor, it is possible to detect variations in eddy current flow directions which tend to be more pronounced for UXO objects compared to scrap.

Moreover, since magnetometers are significantly smaller than dB/dt coil type sensors, it becomes possible to package a 3 component sensor into a relatively small space.

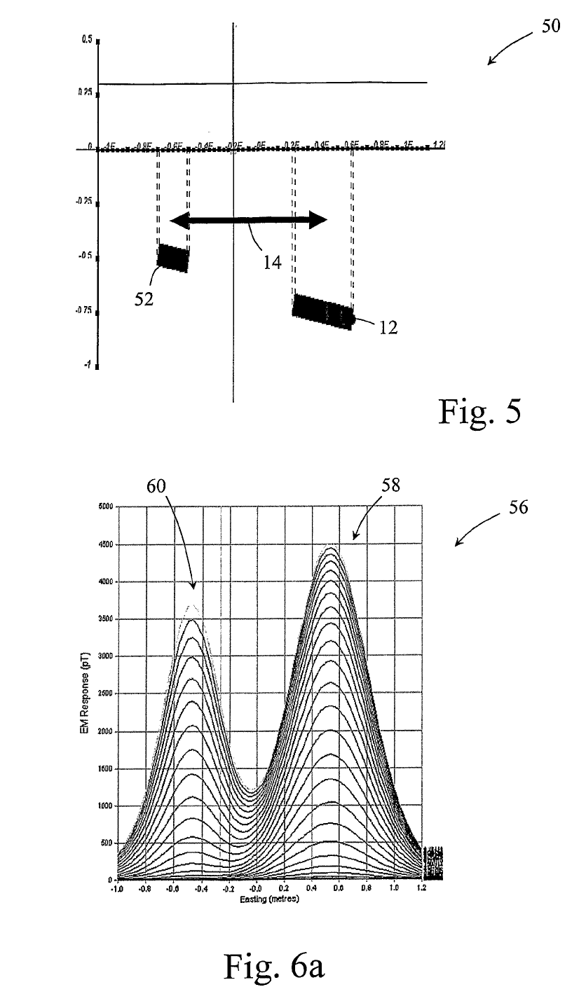

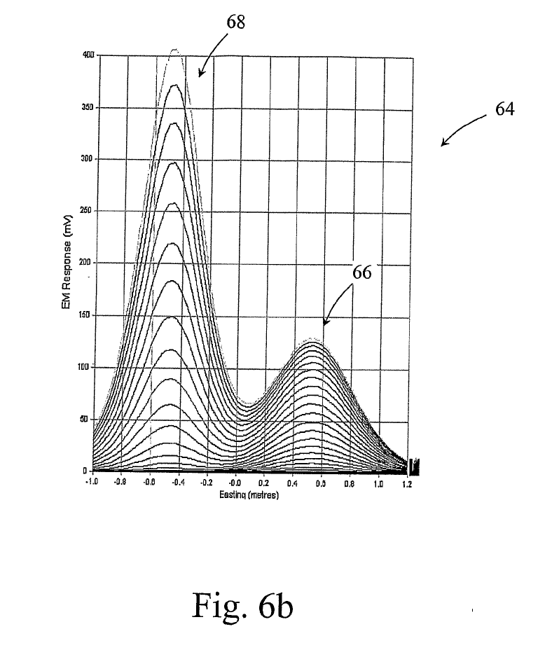

FIG. 5 shows a simple model 50 of a UXO 12 and scrap metal 52 of the same conductivity but different size and burial depth in a resistive half-space. FIG. 6a shows a modeled response 56 for a B field sensor for the Z component of the response magnetic field over the two targets and FIG. 6b shows a corresponding modeled response 64 for a dB/dt sensor.

It is clear from the simple model shown in FIGS. 5, 6a and 6b that the B-field sensor produces a stronger response 58 over the larger UXO target 12 than the response 60 over the scrap 52, even though the UXO target 12 is at greater depth. In contrast, the dB/dt sensor produces a stronger response 68 over the scrap 52 than the response 66 over the UXO 12. Decay curve analysis of the dB/dt response will also show the UXO target 12 to be the larger target since the decay rate is slower for the larger UXO 12 than for the smaller scrap target 52.

The primary field at the center of the transmitter 14 used for UXO detection is typically three orders of magnitude higher than that at the center of a typical transmitter used for mineral exploration. This high field places very large linearity requirements on the sensing device because the desired measurement of off-time decay of induced target response is disturbed if the sensor is driven into a mode of non-linear response by the strong primary fields associated with the on-time pulse. The effects of such high fields on the sensors can be at least partly ameliorated by including nulling coils in the metal detector 10, 30, 36 which serve to reduce the primary magnetic field magnitude at the sensitive areas 80 of the sensors 16, 18, 20.

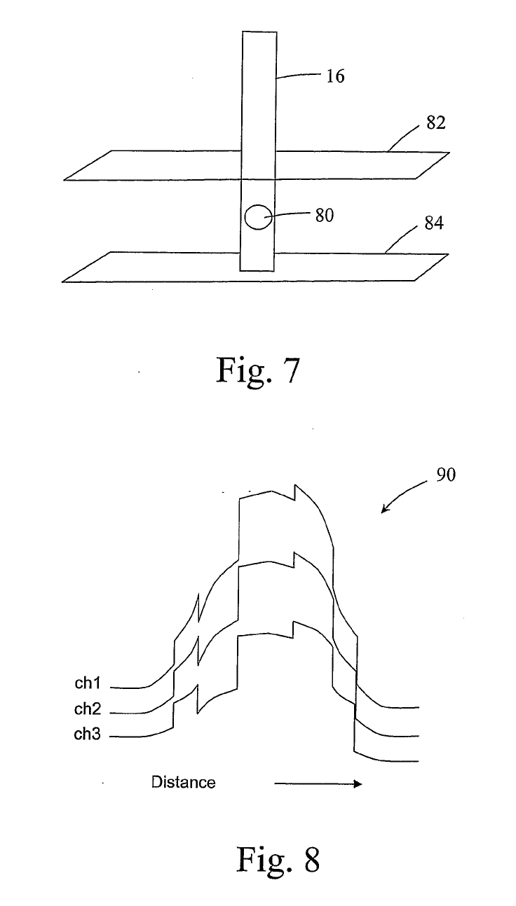

Referring to FIG. 7, an arrangement for incorporating nulling coils into the sensors 16, 18, 20 is shown diagrammatically. As can be seen in FIG. 8, assuming a sensitive area 80 of a sensor 16, a first nulling coil 82 is disposed above the sensitive area 80, and a second nulling coil 84 is disposed below the sensitive area 80. In this example, the nulling coil is a Helmholtz type coil of generally square 0.2 m×0.2 m configuration and is energized with a current of sufficient magnitude so that the primary field from the transmitter coil 14 is closely nulled to 1 part in 100 or better at the sensitive area 80. In this embodiment, the nulling coils are connected in series with the transmitter and are of such size and spacing and number of wire turns that nulling is substantially achieved at the sensitive area 80 when passing the transmitter current through the series connection of transmitter and nulling coils.

In order to produce usable data, the electromagnetic time-domain response data is processed by the control unit 22 so as to:

a. level the results profiles; and

b. strip the self response of the sensors from the results profiles.

Referring to FIG. 8, diagrammatic exemplary self response profiles 90 for the X component of a three component magnetometer are shown. As can be seen, the profiles show step changes between readings, which may be systematic or random in nature, but affect all time channels ch1, ch2, ch3 equally.

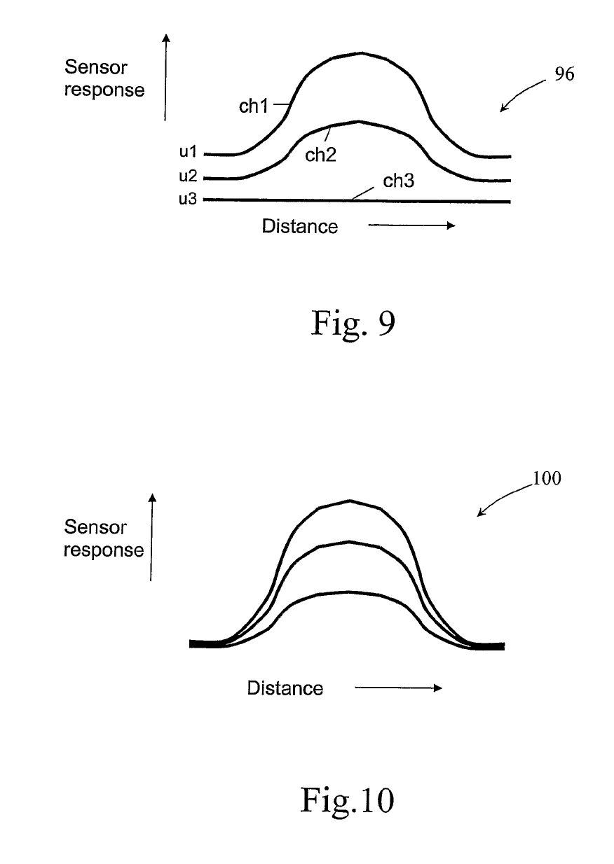

Using the lowest amplitude channel (channel 3 in this case) as a reference channel, the profiles 90 are leveled by subtracting the amplitude of the reference channel ch3 from each of the other channels ch1 and ch2 to produce leveled profiles 96, as shown in FIG. 9.

The leveled profiles 96 continue to show a background response or instrument self response which may be a constant shift u1, u2, u3 in amplitude from zero, or may be approximated as a linear trend. In the present example, since channel 3 has been used to level the data, the shift in channel 3 will be zero (u3=0).

The background response or instrument self response is removed (stripped) from the leveled profiles 96 by subtracting a background response u1, u2, u3 associated with a channel from all readings for that channel. For example, value u1 is subtracted from all readings for channel 1, value u2 is subtracted from all readings for channel 2, and value u3 is subtracted from all readings for channel 3. Leveled and stripped profiles are shown in FIG. 10.

Alternatively, a linear trend may be subtracted from each channel such as:

v′(x)=x(v1−u1)/(x2−x1)

where v′(x) is the background level subtracted from the reading at profile position x.

The values of x1,x2 may be selected as a moving window along a profile so as to create a continuously variable value of v′(x) to use in the subtraction of instrument self response.

The leveling algorithm assumes that the decay curve is sampled to sufficiently late times that the decay has reached zero. The time window where the decay is assumed to be zero is termed the reference window. In practice, signals detected in the reference window contain noise, and the noise level can be reduced by using a wide time range for the reference window. In the present example, sample times of the order of 70 msec to 113 msec are used as the reference window.

In the following example, a Zonge ZT-20 transmitter is used which transmits into a 10-turn transmitter loop having an operative current 1 A and moment 10 Am². Three sensors 16, 18, 20 are used in a configuration corresponding to FIG. 2 and in this example commercially-available SQUID magnetometers are used. Nulling coils are also included and the nulling coils are energized such that the primary field at the sensitive area 80 of the sensors before nulling is 1100 nT and after nulling is 25 nT.

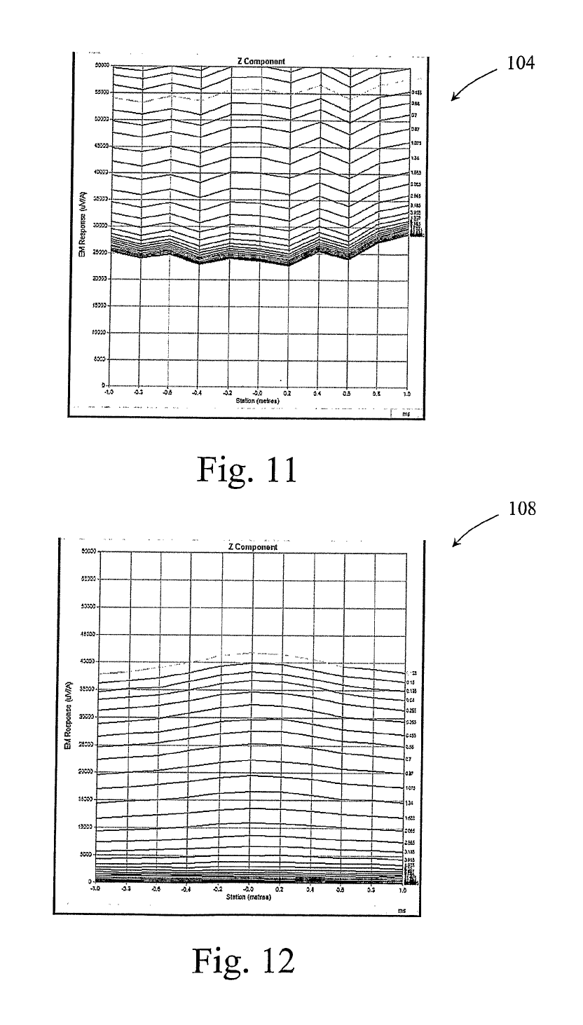

Without leveling, as shown in FIG. 11, the profiles 104 for the Z component appear meaningless. After leveling, as shown in FIG. 12, smooth profiles 108 are obtained for each time window, although a large vertical separation exists between time channels due to the large background or self response of the SQUID sensor.

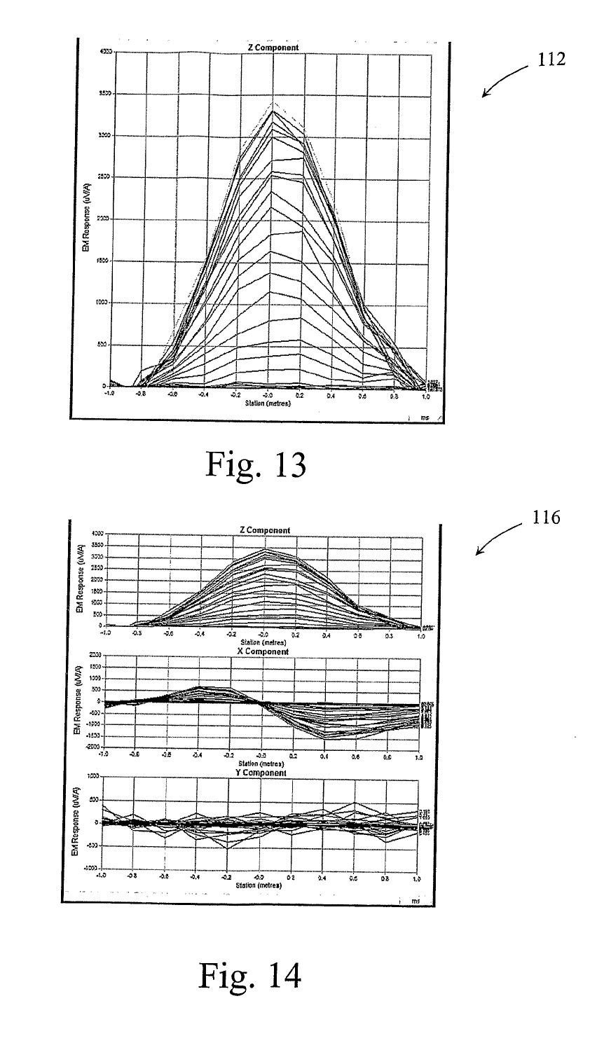

After stripping the self response, as shown in FIG. 13, a meaningful set of profiles 112 is produced, which is the genuine signature of a copper pipe target.

A set of leveled and stripped profiles 116 for X, Y and Z components is shown in FIG. 14. The X-component shows an asymmetry in the placement of the target copper pipe. The Y-component is noise only, since the target is not laterally offset from the profile.

Modifications and variations as would be apparent to a skilled addressee are deemed to be within the scope of the present invention.

1. A metal detector comprising:
a transmitter arranged to generate a primary magnetic field; and
at least one sensor arranged so as to sense a secondary magnetic field vector present after the transmitter has been turned off by measuring 3 substantially mutually orthogonal components of the secondary magnetic field;
wherein each sensor is of a type arranged to sense a time-varying magnetic field.

2. A metal detector as claimed in claim 1, comprising a plurality of sensors.

3. A metal detector as claimed in claim 2, wherein the transmitter comprises a coil and the metal detector comprises a first sensor disposed substantially centrally of the transmitter coil, a second sensor disposed adjacent and inwardly of a first side of the transmitter coil, and a third sensor disposed adjacent and inwardly of a second opposite side of the transmitter coil.

4. A metal detector as claimed in claim 2, wherein the transmitter is in the form of a coil and the metal detector comprises a first sensor disposed substantially centrally of the transmitter coil, a second sensor disposed adjacent and outwardly of a first side of the transmitter coil, and a third sensor disposed adjacent and outwardly of a second opposite side of the transmitter coil.

5. A metal detector as claimed in claim 4, wherein the distances of the second and third sensors from the first and second sides of the transmitter coil are selected such that the primary field at each of the second and third sensors is substantially equal and opposite to the primary field at the first sensor.

6. A metal detector as claimed in claim 2, wherein the transmitter is in the form of a coil and the metal detector comprises a first sensor being disposed substantially centrally of the transmitter coil, a second sensor disposed outwardly of a first side of the transmitter coil, and a third sensor disposed outwardly of a second opposite side of the transmitter coil, the distance between adjacent sensors being approximately equal to the length of a side of the transmitter coil.

7. A metal detector as claimed in any one of the preceding claims, wherein the metal detector further comprises means for reducing the magnitude of the primary field at an active area of each sensor.

8. A metal detector as claimed in claim 7, wherein the means for reducing the primary field magnitude comprises at least one nulling coil.

9. A metal detector as claimed in claim 8, wherein two nulling coils are provided for each sensor, a first nulling coil being disposed at a location upwardly of the sensor, and a second nulling coil disposed downwardly of the sensor.

10. A metal detector as claimed in claim 8 or claim 9, wherein the or each nulling coil is connected in series with a transmitter coil and is arranged such that nulling is substantially achieved at the or each sensor when a transmitter current is passed through the transmitter and at least one nulling coil.

11. A metal detector as claimed in any one of the preceding claims, wherein the metal detector further comprises a control unit arranged to process response data produced by the or each sensor so as to reduce anomalies in the response data.

12. A metal detector as claimed in claim 11, wherein the control unit is arranged to process the response data so as to produce leveled data by selecting a reference channel from a plurality of data channels produced by the or each sensor and subtracting the amplitude of the reference channel from each of the other channels.

13. A metal detector as claimed in claim 11 or claim 12, wherein the control unit is arranged to process the response data so as to produce stripped data by subtracting a background response amplitude from each of the channels produced by the or each sensor.

14. A metal detector as claimed in claim 11 or claim 12, wherein the control unit is arranged to process the response data so as to produce stripped data by subtracting a linear trend from each of the channels produced by the or each sensor.

15. A metal detector as claimed in claim 14, wherein the linear trend is defined as:
v′(x)=x(v1−u1)/(x2−x1)
where v′(x) is the background level subtracted at profile position x, and x1-x2 are selected as a moving window along a profile.

16. A method of detecting metal, said method comprising:
generating a primary magnetic field;
turning the primary magnetic field off; and
sensing 3 mutually orthogonal components of a secondary magnetic field vector present after the primary magnetic field has been turned off.

17. A method as claimed in claim 16, comprising providing a plurality of sensors.

18. A method as claimed in claim 16 or claim 17 comprising reducing the magnitude of the primary field at an active area of each sensor.

19. A method as claimed in claim 18, comprising reducing the primary field magnitude using at least one nulling coil.

20. A method as claimed in claim 19, comprising disposing a first nulling coil at a location upwardly of a sensor, and disposing a second nulling coil downwardly of the sensor.

21. A method as claimed in claim 19 or claim 20, comprising converting the or each nulling coil in series with a transmitter coil.

22. A method as claimed in any one of claims 16 to 21, further comprising:
for each sensor and for each component of the secondary magnetic field, selecting a reference channel from a plurality of data channels produced by the sensor and subtracting the amplitude of the reference channel from each of the other channels so as to produce leveled data.

23. A method as claimed in any one of claims 16 to 22, further comprising:
for each sensor and for each component of the secondary magnetic field, subtracting a background response amplitude from each of the response amplitudes produced by the component so as to produce stripped data.

24. A device for detecting a UXO, the device including a metal detector as claimed in any one of claims 1 to 15.

25. A metal detector substantially as hereinbefore described with reference to, and as shown in, the accompanying drawings.
